(19) United States
(12) Patent Application Publication
(10) Pub. No.: US 2011/0247686 A1
(43) Pub. Date: Oct. 13, 2011

(54) MULTILAYER FILM FOR PHOTOVOLTAIC APPLICATIONS

(75) Inventors: Christian C. Honeker, Acton, MA (US); Maryann C. Kenney, Foxboro, MA (US); Julia DiCorleto Gibson, Bedford, MA (US); Keith C. Hong, Lititz, PA (US)

(73) Assignee: SAINT-GOBAIN PERFORMANCE PLASTICS CORPORATION, Aurora, OH (US)

(21) Appl. No.: 13/046,577

(22) Filed: Mar. 11, 2011

Related U.S. Application Data
(60) Provisional application No. 61/313,567, filed on Mar. 12, 2010.

(51) Int. Cl. H01L 31/0216; B32B 38/00; H01L 31/18; B32B 37/12

(52) U.S. Cl. 136/256; 156/60; 156/280

(57) ABSTRACT

A multilayer film includes a functional portion including one or more layers, an adhesive layer overlying a major surface of the functional portion, and a fluoropolymer layer overlying a major surface of the adhesive layer opposite the functional portion. The fluoropolymer layer includes a fluoropolymer. The adhesive layer includes an adhesive and an ultraviolet radiation absorber.

### CROSS REFERENCE TO RELATED APPLICATION(S)

The present application claims priority from U.S. Provisional Patent Application No. 61/313,567, filed Mar. 12, 2010, entitled “MULTILAYER FILM FOR PHOTOVOLTAIC APPLICATIONS,” naming inventors Christian C. Honeker, Keith C. Hong, Maryann C. Kenney, and Julia DiCorleto, which application is incorporated by reference herein in its entirety.

### FIELD OF THE DISCLOSURE

This disclosure, in general, relates to multilayer films and photovoltaic devices formed therefrom.

### BACKGROUND

With increasing energy prices and with increasing concern over the environmental impact of hydrocarbon fuels, industry is turning to alternative energy sources, such as solar power. In particular, industry is turning to photovoltaic devices which convert sunlight into electrical current. Although photovoltaic devices represent low ongoing operational costs, much of the expense of installing a photovoltaic device is in upfront equipment costs. As such, economic viability of a photovoltaic device is strongly dependent upon equipment cost and durability.

During use, photovoltaic devices are exposed to extreme weather conditions. To protect the photovoltaic devices, encapsulants and other polymer films are disposed over the surfaces of the photovoltaic devices. However, such encapsulants and other polymer films are themselves susceptible to extreme weather conditions and over time may degrade. Such degradation reduces the effectiveness of encapsulants and polymer films, leading to damage to the photovoltaic devices.

Durability concerns influence the competitiveness of photovoltaic systems relative to other energy sources. Despite the attractiveness of the low environmental impact of solar energy solutions, photovoltaic devices are struggling to provide electricity at existing grid prices. A reduction in durability severely hampers the viability of existing photovoltaic operations.

As such, an improved photovoltaic system would be desirable.

### SUMMARY

In an embodiment, a multilayer film includes a functional portion including one or more layers; an adhesive layer overlying a major surface of the functional portion, the adhesive layer comprising an adhesive and an ultraviolet radiation absorber; and a fluoropolymer layer overlying a major surface of the adhesive layer opposite the functional portion, the fluoropolymer layer including a fluoropolymer.

In a particular embodiment, a photovoltaic device includes a photovoltaic component; a first polymer layer overlying a major surface of the photovoltaic component; a second polymer layer overlying a major surface of the first polymer layer opposite the photovoltaic component, the second polymer layer including an adhesive and an ultraviolet radiation absorber; and a third polymer layer overlying a major surface of the second polymer layer opposite the first polymer layer, the third polymer layer including a fluoropolymer.

In another embodiment, a method of forming a multilayer film includes dispensing a fluoropolymer layer; coating an adhesive layer on a surface of the fluoropolymer layer, the adhesive layer comprising an adhesive and an ultraviolet radiation absorber; and laminating the fluoropolymer layer and the adhesive layer to a functional layer, the adhesive layer in contact with the functional layer.

### BRIEF DESCRIPTION OF THE DRAWINGS

The present disclosure may be better understood, and its numerous features and advantages made apparent to those skilled in the art by referencing the accompanying drawings.

FIG. 1, FIG. 2, FIG. 3, and FIG. 4 include illustrations of exemplary photovoltaic devices.

FIG. 5, FIG. 6, FIG. 7 and FIG. 8 include graphs of transmission of the UV and visible light spectrums.

The use of the same reference symbols in different drawings indicates similar or identical items.

### DESCRIPTION OF THE PREFERRED EMBODIMENT(S)

In an exemplary embodiment, a photovoltaic device includes a photovoltaic component and a multilayer laminate overlying a major surface of the photovoltaic component. The multilayer laminate includes a fluoropolymer layer forming an outer surface of the photovoltaic device, an adhesive layer or tie layer disposed under a major surface of the fluoropolymer layer opposite the outer surface, and a functional portion disposed under a major surface of the adhesive or tie layer opposite the fluoropolymer layer and closest to the photovoltaic component. The adhesive or tie layer includes an ultraviolet radiation absorber and can include a light stabilizer or antioxidant. Optionally, an encapsulant can be disposed between the multilayer laminate and the photovoltaic component or can be part of the multilayer laminate.

In a further embodiment, a method of forming a photovoltaic device includes dispensing a photovoltaic component and applying a multilayer laminate to overlie a major surface of the photovoltaic component. Optionally, an encapsulant can be applied to overlie the photovoltaic component prior to applying the multilayer laminate.

In the embodiments described herein, the photovoltaic components include at least two major surfaces. The term “front surface” refers to the surface of the photovoltaic device that receives the greater proportion of direct sunlight. In embodiments, the front surface is the active side of the photovoltaic device that converts sunlight to electricity. However, in some embodiments, the photovoltaic device can be constructed such that two surfaces of the device are active. For example, the front surface can convert direct sunlight to electricity, while the back surface can convert reflected sunlight to electricity. In other examples, the front surface can receive direct sunlight at one point during the day and the back surface at another point during the day. The embodiments described herein can include such photovoltaic constructions or other similar photovoltaic constructions. The terms “over,” “overlie,” “under,” or “underlie” refer to the disposition of a layer, film or laminate relative to a major surface of an adjacent structure in which “over” or “overlie” mean the layer, film or laminate is relatively closer to an outer surface of a photovoltaic device and “under” or “underlie” mean the layer, film or laminate is relatively further from an outer surface of the photovoltaic device. Herein, the terms “on,” “over,” “overlie,” “under,” and “underlie” can permit inclusion of intermediate structures between the surface and the recited structure.

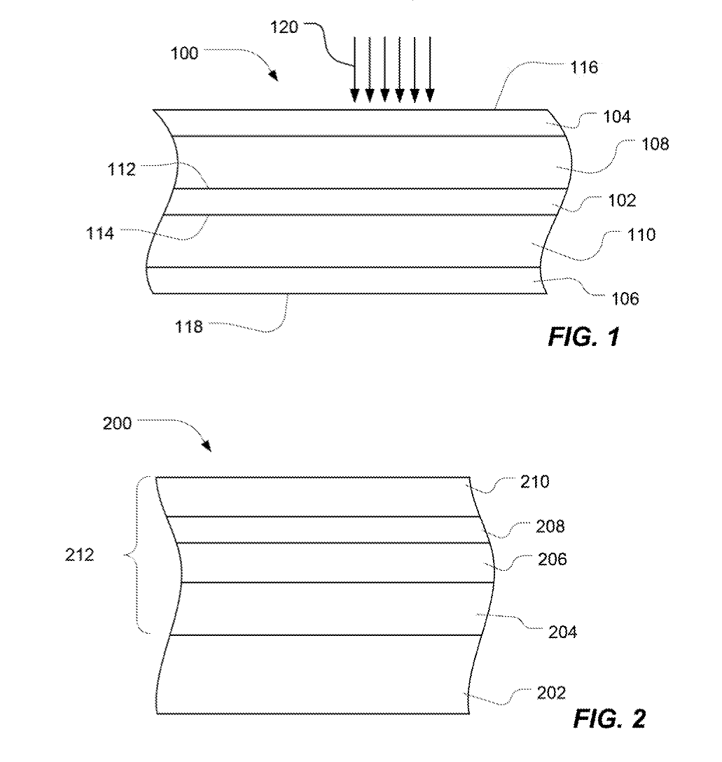

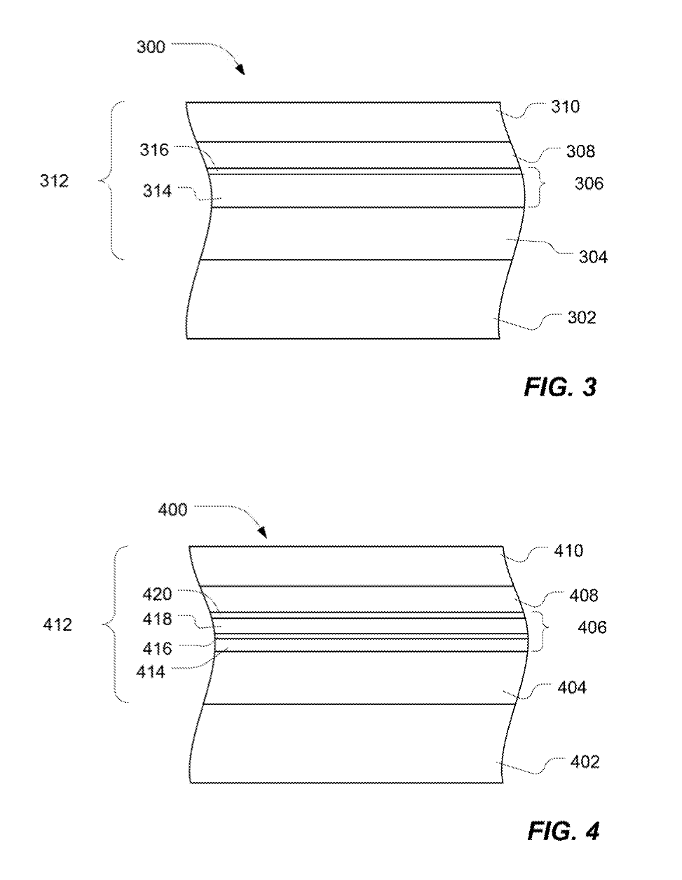

As illustrated in FIG. 1, a photovoltaic device 100 includes a photovoltaic component 102. The component 102 includes a front surface 112 and a back surface 114. The front surface 112 includes elements to receive sunlight 120 and convert the sunlight 120 into electrical current. In a particular example, the back surface 114 can be defined by a support for the elements of the front surface 112.

A protective film 104 can be disposed over the front surface 112. The protective film 104 can form an outer surface 116 configured to receive light, such as sunlight, to be converted to energy by the photovoltaic component 102. One or more intermediate layers 108 can be disposed between the protective layer 104 and the front surface 112.

In addition, a protective film 106 can be disposed over the back surface 114. The protective film 106 can form a back side outer surface 118. In addition, one or more intermediate layers 110 can be disposed between the back surface protective film 106 and the back surface 114. In an example, the one or more layers 108 or 110 can include an encapsulant. Encapsulants are materials that help protect the photovoltaic device. Such materials include, for example natural or synthetic polymers including polyethylene (including linear low density polyethylene, low density polyethylene, high density polyethylene, etc.), polypropylene, nylons (polyamides), EPDM, polyesters, polycarbonates, ethylene-propylene elastomer copolymers, copolymers of ethylene or propylene with acrylic or methacrylic acids, acrylates, methacrylates, ethylene-propylene copolymers, poly alpha olefin melt adhesives such including, for example, ethylene vinyl acetate (EVA), ethylene butyl acrylate (EBA), ethylene methyl acrylate (EMA); ionomers (acid functionalized polyolefins generally neutralized as a metal salt), acid functionalized polyolefins, polyurethanes including, for example, thermoplastic polyurethane (TPU), olefin elastomers, olefinic block copolymers, thermoplastic silicones, polyvinyl butyral, a fluoropolymer, such as a terpolymer of tetrafluoroethylene, hexafluoropropylene, and vinylidene fluoride; or any combination thereof.

In a particular example, the protective films 104 and 106 can be multilayer films including a fluoropolymer layer forming the outer surface, an adhesive or tie layer underlying the fluoropolymer layer, and a functional portion underlying the adhesive or tie layer. For example, the functional portion can function as a barrier to hinder water vapor transmission, corrosive gas diffusion, or a combination thereof.

FIG. 2 includes an illustration of a further example of a portion 200 of a photovoltaic device, which includes a photovoltaic component 202 and a protective film 212. The portion 200 can be a front portion or a back portion of the photovoltaic device. Optionally, an encapsulant layer 204 can be disposed between the protective film 212 and the photovoltaic component 202 or the encapsulant 204 can form part of the protective film 212.

In an example, the protective film 212 includes an outer layer 210. The outer layer 210 can include a fluoropolymer. For example, the outer layer 210 can be formed of a fluoropolymer, such as polyvinylidene fluoride (PVDF), polyvinyl fluoride (PVF), polytetrafluoroethylene (PTFE), a copolymer of tetrafluoroethylene and perfluoro methylvinylether (PFA), ethylene tetrafluoroethylene copolymer (ETFE), polychlorotrifluoroethylene (PCTFE), ethylene chlorotrifluoroethylene copolymer (ECTFE), fluorinated ethylene propylene copolymer (FEP), a copolymer of ethylene and fluorinated ethylene propylene (EFEP), a terpolymer of tetrafluoroethylene, hexafluoropropylene, and vinylidene fluoride (THV), a terpolymer of tetrafluoroethylene, hexafluoropropylene, and ethylene (HTE), or any combination thereof. In a particular example, the outer layer 210 includes at least 70% fluoropolymer, such as at least 85% fluoropolymer, at least 95% fluoropolymer, at least 98% fluoropolymer, or consists essentially of fluoropolymer, having the chemical resistance and weatherability of the fluoropolymer. In a particular example, the outer layer 210 includes ethylene-tetrafluoroethylene copolymer (ETFE). In another example, the outer layer 210 includes fluorinated ethylene propylene copolymer (FEP). In a further example, the outer layer includes polyvinyl fluoride (PVF).

In an example, the outer layer 210 has a thickness in a range of 0.5 mils to 20 mils. For example, the outer layer 210 can have a thickness in a range of 0.5 mils to 10 mils, such as a range of 0.5 mils to 5 mils, or even 0.5 mils to 2 mils.

In addition, the protective film 212 includes an adhesive layer or tie layer 208. As illustrated, the adhesive layer or tie layer 208 underlies the outer layer 210. In an example, the adhesive layer 208 is in direct contact with the outer layer 210 without intervening layers. The adhesive layer 208 can include an adhesive and an ultraviolet radiation absorber. In addition, the adhesive layer 208 can optionally include a light stabilizer and can optionally include an antioxidant.

An exemplary adhesive includes a polyurethane, ethylene vinyl acetate (EVA), polyester (PET), a cynoacrylate, epoxy, phenolics, an olefin, hot melt adhesives, ionomers, silicone, acrylics, a copolymer thereof, or a combination thereof. Alternatively, the layer 208 can be a tie layer formed of an encapsulant, such as an encapsulant described above in relation to layers 108 and 110 of FIG. 1. In a particular example, the adhesive includes polyurethane, such as an aliphatic polyurethane. In another example, the adhesive includes EVA. In a particular example, the adhesive is an optically clear adhesive (OCA). An OCA has an internal transmittance of at least 99% and a haze of less than 1%. Internal transmittance is calculated in accordance with the definition of internal transmittance found in ASTM E284. Haze is measured in accordance with ASTM D1003-92. For example, the adhesive can be an acrylic OCA. In another example, the adhesive can be a polyurethane OCA or a polyurethane ester OCA. Exemplary OCAs are available from 3M, Toyo Ink, or Sochem. For instance, the OCA in the adhesive layer can provide the optimum light transmission to a photovoltaic device, thereby increasing the efficiency of the device to convert sunlight to electrical current.

In addition, the adhesive layer 208 includes an ultraviolet radiation absorber. In an example, the ultraviolet radiation absorber is selected from an organic ultraviolet radiation absorber, such as an ultraviolet radiation absorber of the benzotriazole class, the triazine class, the benzophenone class, the cyanoacrylate class, the benzoxazinone class, the oxanilide class, or combinations thereof. For example, the ultraviolet radiation absorber may be a benzotriazole class absorber, such as 2,4-di-tert-butyl-6-(5-chlorobenzotriazol-2-yl)phenol or 2-(2H-benzotriazol-2-yl)-p-cresol. In another example, the ultraviolet radiation absorber is of the triazine class, such as 2-(4,6-diphenyl-1,3,5-triazin-2-yl)-5-hexyloxy-phenol. Other exemplary ultraviolet radiation absorbers are available from BASF under the name Tinuvin® or Chemisorb®, or are available from Cytech Industries under the tradename Cyasorb.

In another example, the ultraviolet radiation absorber includes an inorganic ultraviolet radiation absorber. For example, the inorganic ultraviolet radiation absorber can include titanium dioxide or zinc oxide. In particular, the inorganic ultraviolet radiation absorber has a particle size not greater than 100 nm, such as a particle size in a range of 1 nm to 100 nm.

In a particular example, the adhesive layer 208 is free of inorganic species, such as ceramic species. For example, the ultraviolet radiation absorber may not include titanium dioxide or zinc oxide.

The adhesive layer 208 can include the ultraviolet radiation absorber in an amount in a range of 0.5 wt % to 20 wt %, such as a range of 0.5 wt % to 10 wt %. In particular, the adhesive layer 208 can include at least 5.5 wt % of the ultraviolet radiation absorber, such as at least 7.0 wt % of the ultraviolet radiation absorber. In a further example, the adhesive layer 208 does not include greater than 20.0 wt % of the ultraviolet radiation absorber. In an example, the adhesive layer 208 includes ultraviolet radiation absorber in an amount from 5.0 wt % to 20 wt %, such as 5.0 wt % to 10 wt %, or even 5.5 wt % to 10 wt %. In contrast, typical commercially available adhesive formulations generally do not contain ultraviolet radiation absorber additive at greater than 2 wt %. At levels greater than 2 wt %, commercially available adhesive formulations typically show evidence of precipitation or segregation of the additive from the adhesive. In an exemplary embodiment of the present invention, even at levels greater than 5.0 wt %, the ultraviolet radiation absorber is non-precipitating, i.e. is compatible with the adhesive component in the adhesive layer 208.

In addition, the adhesive layer 208 can include a light stabilizer, such as a hindered amine light stabilizer (HALS). An exemplary HALS stabilizer includes bis(2,2,6,6,-tetramethyl-4-piperidyl)sebacate. For example, the adhesive layer 208 can include the light stabilizer in an amount in a range of 0.1 wt % to 5 wt %. In an example, the adhesive layer 208 includes at least 2.5 wt % of the light stabilizer, such as at least 3.5 wt %, or even at least 5.0 wt % of the light stabilizer. An exemplary light stabilizer is available as Tinuvin® 770 from BASF or as Cyasorb THT-4611 from Cytech Industries.

In a further example, the adhesive layer 208 can include an antioxidant. For example, the adhesive layer 208 can include an antioxidant in an amount in a range of 0.5 wt % to 5 wt %, such as a range of 1.0 wt % to 3 wt %. An exemplary antioxidant includes a phosphite antioxidant, a phenolic antioxidant, a sulfide antioxidant, an amine antioxidant, or a combination thereof. For example, the antioxidant can be a phosphite antioxidant. In another example, the antioxidant can be a phenolic antioxidant. Exemplary antioxidants are available under the tradenames ETHANOX® or ETHAPHOS™ from Albemarle Corporation or under the tradename Irganox® from BASF.

The adhesive layer 208 can have a thickness in a range of 0.2 mils to 30 mils, such as a range of 0.2 mils to 12 mils, 0.2 mils to 2 mils, such as a range of 0.2 mils to 1.5 mils, or a range of 0.5 mils to 1.0 mils. In an embodiment, the adhesive layer 208 can have a thickness in a range of 0.1 mils to 4 mils, such as a range of 0.2 mils to 2 mils, or a range of 0.5 mils to 1.0 mils. Alternatively, the adhesive layer 208 can have a thickness in a range of 2 mils to 10 mils. For example, when the adhesive layer 208 includes EVA, the thickness can be in a range of 2 mils to 30 mils. In another example, when the adhesive layer 208 includes a polyurethane adhesive or acrylic adhesive, the thickness can be in a range of 0.2 mils to 2 mils.

In a particular example, the adhesive layer 208 bonds to the outer layer 210, including fluoropolymer, with a peel strength of at least 2.0 Newton per centimeter, at least 4 Newton per centimeter, at least 5 Newton per centimeter or even greater than 6.0 Newton per centimeter.

As illustrated in FIG. 2, the protective film 212 includes a functional layer or layers 206 underlying the adhesive layer 208. In an example, the functional layer or layers 206 form a functional portion that includes at least one barrier layer to inhibit water vapor transfer, corrosive gas transfer, such as oxygen transfer, or a combination thereof. For example, the functional layer or layers 206 can have a water vapor transmission rate of not greater than 0.8 g/m² day, such as not greater than 0.4 g/m² day, or even not greater than 0.2 g/m² day. In a particular example, the water vapor transmission rate may be not greater than 0.1 g/m² day, such as not greater than 0.01 g/m² day, not greater than 0.001 g/m² day, not greater than 10⁻⁴ g/m² day, or even not greater than 10⁻⁵ g/m² day. While the functional layer or layers 206 are illustrated as a single layer, the functional layer or layers 206 can include more than one layer. The functional layer or layers 206 typically have a total thickness in a range of 0.1 mil to 10 mils, in a range of 0.1 mil to 7 mils, such as in a range of 0.5 mil to 4 mils.

In a particular example, the functional layer or layers 206 include at least one barrier layer, which can include a barrier polymer. An exemplary barrier polymer includes polyester, polycarbonate, or any combination thereof. An exemplary polyester can include polyethylene terephthalate (PET) or polyethylene naphthalate (PEN). In another example, the polyester includes a liquid crystal polymer. An exemplary liquid crystal polymer includes aromatic polyester polymers, such as those available under tradenames XYDAR® (Amoco), VECTRA® (Hoechst Celanese), SUMIKOSUPER™ or EKONOL™ (Sumitomo Chemical), DuPont HX™ or DuPont ZENITE™ (E.I. DuPont de Nemours), RODRUN™ (Unitika), GRANLAR™ (Grandmont), or any combination thereof. Preferred liquid crystal polymers include thermotropic (melt processable) liquid crystal polymers wherein constrained microlayer crystallinity can be particularly advantageous.

In a further example, the barrier layer can include an inorganic layer deposited on the surface of the barrier polymer. For example, the inorganic layer can include metal, metal oxide, metal nitride, metal carbide, or a combination thereof. In an example, the metal can include aluminum, silver, gold, titanium, tin, zinc, or a combination thereof. An exemplary metal oxide can include alumina, silica, tin oxide, zinc oxide, or a combination thereof. An exemplary metal nitride can include aluminum nitride, titanium nitride, silicon nitride, zinc nitride or a combination thereof. An exemplary carbide can include silicon carbide, aluminum carbide, titanium carbide, or a combination thereof. The thickness of the inorganic layer can be in a range of 20 nm to 1000 nm, such as a range of 50 nm to 500 nm, or even a range of 50 nm to 200 nm.

For example, as illustrated in FIG. 3, a protective film 312 overlies a photovoltaic component 302. Optionally, an encapsulant 304 forms part of the protective film 312 closest to the photovoltaic component 302, the encapsulant 304 underlying barrier layers 306. The protective film 312 includes a fluoropolymer layer 310, an adhesive layer 308 or tie layer, and the barrier layers 306. The barrier layers 306 overlie a major surface of the photovoltaic component 302. The adhesive layer 308 overlies a major surface of the barrier layers 306 opposite the photovoltaic component 302, and the fluoropolymer layer 310 overlies a major surface of the adhesive layer 308 opposite the barrier layers 306. The fluoropolymer layer 310 can form an outer surface of the photovoltaic device 300.

The barrier layers 306 include a barrier polymer layer 314 on which an inorganic material layer 316 is disposed. As illustrated, the inorganic material layer 316 is disposed on a surface of the barrier polymer layer 314 opposite the photovoltaic component 302 and in proximity to the adhesive layer 308. Alternatively, the inorganic material layer 316 can be disposed on a major surface of the barrier polymer layer 314 closest to the photovoltaic component 302.

In a further example illustrated in FIG. 4, a protective film 412 overlies a photovoltaic component 402 and includes a multilayer barrier portion 406. An encapsulant 404 forms part of the protective film 412 closest to the photovoltaic component 402, the encapsulant 404 underlying the barrier portion 406. The protective film 412 includes a fluoropolymer layer 410, an adhesive layer 408 or tie layer, and the barrier portion 406. The barrier portion 406 overlies a major surface of the photovoltaic component 402. The adhesive layer 408 overlies a major surface of the barrier portion 406 opposite the photovoltaic component 402, and the fluoropolymer layer 410 overlies a major surface of the adhesive layer 408 opposite the barrier portion 406. The fluoropolymer layer 410 can form an outer surface of the photovoltaic device 400.

The barrier portion 406 can include more than one set of barrier polymer layers and inorganic material layers. As illustrated, the barrier portion 406 includes a barrier polymer layer 414 on which an inorganic material layer 416 is disposed. In addition, a barrier polymer layer 418 can be disposed on the inorganic material layer 416, and an inorganic material layer 420 can be disposed on the barrier polymer layer 418. In an embodiment, other organic polymer layers may be disposed directly on the inorganic material layer. While two sets of barrier polymer layers (414 and 418) and inorganic material layers (416 and 420) are illustrated, additional sets of barrier polymer layers and inorganic material layers can be included. For example, the barrier portion 406 can include at least three sets of barrier polymer layers and inorganic polymer layers, such as at least four sets, or even at least five sets. In an embodiment, the sets of layers further include organic polymer layers disposed directly on the inorganic material layers. In a further example, the sets of layers can be in direct contact. Alternatively, the sets of layers can have an adhesive layer between sets of layers, such as an adhesive layer formed of an adhesive described above.

In a further example (not illustrated), the barrier portion of a protective film can include a microlayer portion including layers (microlayers) having a thickness of not greater than 5 micrometers. A microlayer portion can include at least three repeating units. In an example, each repeating unit includes at least two layers. A layer of the repeating unit has a thickness of not greater than 5 micrometers. In an embodiment, each of the layers of the repeating unit has a thickness of not greater than 10 micrometers. In another embodiment, only one of the layers within the repeating unit can have a thickness of not greater than 5 micrometers. A layer of the repeating unit can include a barrier polymer. In another example, a layer of the repeating unit can include an adhesive layer as described above. In a further example, a layer of the repeating unit can include inorganic filler, such as particles formed of the metal, metal oxide, metal nitride, metal carbide, or combinations thereof, described above.

In an additional example, the barrier polymer can include additives such as a scavenger compound, such as a desiccant or a getter. A getter is a material that is reactive with the species that it is intended to scavenge, such as water, oxygen, or other compounds, and a desiccant is a material that absorbs or reacts to water. An exemplary scavenger compound includes a metal scavenger, a metal oxide or hydroxide scavenger, a metal sulfate scavenger, a metal halide scavenger, a metal silicate, other inorganic scavengers, an organometallic scavenger, a metal ligand, organic scavengers, or any combination thereof. In an example, a metal scavenger includes an alkali metal, such as lithium; an alkaline earth metal, such as beryllium, calcium, magnesium, or barium; a transition metal, such as iron, manganese, palladium, zirconium, cobalt, copper, zinc, titanium, or chromium; other metals, such as aluminum; alloys thereof, or any combination thereof. An exemplary metal oxide scavenger includes dehydrated or partially dehydrated oxides of the above metals, such as calcium oxide, barium oxide, cobalt oxide, magnesium oxide, alumina, titanium oxide, zirconia, zinc oxide, or any combination thereof. An exemplary metal halide can include a halide or perchlorate of a metal listed above, or an exemplary metal sulfate can include a sulfate of a metal listed above, such as calcium sulfate, barium sulfate, copper sulfate, or any combination thereof. Another inorganic scavenger can include a montmorillonite clay, a zeolite, activated carbon, silica gel, alumina gel, bauxite, or any combination thereof.

An exemplary organometallic scavenger can include a Lewis acid organometallic compound, a reactive salt thereof, or any combination thereof. In an example, the Lewis acid organometallic compound includes at least one carbon metal bond. An exemplary organometallic compound has the formula:

[MR¹ₘR²ₙXₗ]^{-q}

wherein M is a metal; R1 is an alkyl, alkenyl, aryl, heteroaryl, alcohol, or polymeric group, or a substituted moiety thereof, or any combination thereof; R2 is a silyl group, an amine, or an alkoxy group, or any combination thereof; X is an anionic species, such as fluoride, chloride, bromide, iodide, nitrate, sulfate, tetrafluoroborate, hexafluorophosphate, or perchlorate, carboxylate, sulfonate, phosphonate; 1 is 0 or 1; m is 0, 1, 2, or 3; n is 0, 1, 2, or 3; and q is the charge of the complex, generally 0, 1, or 2. The compound can form a salt with a cation, such as alkaline or alkaline earth metal ion.

In an additional example, the scavenger compound can be a metal ligand, such as a ligand of a metal listed above. In an example, the metal ligand can be the product of a multidentate chelate with a metal, such as aluminum.

In a further example, the scavenger compound can be a polymeric compound. For example, the polymeric scavenger can be polyacrylamide, polyacrylate, ethylene maleic anhydride copolymer, carboxy-methyl-cellulose, polyvinyl alcohol copolymers, polyethylene oxide, starch, starch grafted copolymer of polyacrylonitrile, ADP™ available from Sud-Chemie, or any combination thereof. Other scavenger compounds include suberin containing materials, such as cork.

Returning to FIG. 2, the encapsulant 204 can be formed as part of the protective film 212 or can be formed as a separate layer, applied separately to the photovoltaic component 202. The encapsulant 204 can include one or more of the polymers described above in relation to layers 108 or 110 of FIG. 1. In addition, the encapsulant 204 can include a reinforcement or additives. For example, the encapsulant 204 can include a reinforcement, such as a fibrous reinforcement. The fibrous reinforcement can be a woven fibrous reinforcement or a non-woven fibrous reinforcement. In an example, the reinforcement is a woven fibrous reinforcement, such as a glass fabric or scrim. Further, the encapsulant 204 can include additives, such as flame retardants, antioxidants, scavengers, such as a desiccant or a getter, or other additives.

The protective film 212 can have a visible light transmission of at least 85% through the layers of the protective film 212. For example, the visible light transmission can be at least 90%, such as at least 92%. Visible light transmission is defined as light transmission for wavelengths between 400 nm and 750 nm. Visible light transmission includes electromagnetic radiation having wavelength in a range of 400 nm to 750 nm.

In another example, the protective film 212 has a desirable durability. For example, the protective film 212 has a desirable Delta-b Index, defined as the change in b* of the L*a*b* scale (CIE 1976) after a specified period of exposure to UVA radiation or UVB radiation using the method of the examples below. In an embodiment, the protective film 212 has a Delta-b Index of not greater than 5 after 160 hours of UVB exposure. For example, the Delta-b Index of the protective film 212 can be not greater than 3.5, such as not greater than 3.0 after 160 hours of UVB exposure. In particular, the Delta-b Index can be not greater than 10 after 800 hours UVB exposure, such as not greater than 8, or even not greater than 6 after 800 hours UVB exposure. In an embodiment, the protective film 212 has a Delta-b Index of less than 10.0 after 1991 hours of UVA exposure, such as less than 9.0 after 1991 hours of UVA exposure, or even less than 6.0 after 1991 hours of UVA exposure. Although not being bound by theory, it is believed that the level of loading of the ultraviolet radiation absorber in the adhesive layer 208 provides the desirable durability. In another example, the protective film 212 has a desirable Yellowing Index, defined as the change in % transmission at 400 nm after a specified period of exposure to UVB in accordance with the method of the examples below, of not greater than 12.0 after 200 hours of exposure, such as not greater than 10.0, or even not greater than 9.0 after 200 hours of exposure. In a further example, the protective film 212 exhibits a Blocking Index, defined as the % transmission at 330 nm after a specified period of exposure to UVB using the method of the examples below, of not greater than 10.0 after 374 hours of exposure, such as not greater than 5.0, or even not greater than 1.0 after 374 hours of exposure.

In an example, layers of protective film 212 can be coextruded. Alternatively, some layers of the protective film 212 can be coextruded and other layers laminated to the coextruded layers. For example, a barrier film can be formed of a barrier polymer and treated to form an inorganic coating. Separately, the adhesive layer can be applied to a fluoropolymer layer. The adhesive coated fluoropolymer can be laminated to the barrier film. Optionally, an encapsulant layer can be extruded to the barrier film or over the combined barrier film and fluoropolymer layer.

In a particular example, the barrier film can be formed by coating one or more layers of extruded barrier polymer with an inorganic material. For example, a barrier polymer layer can be coated through one or more of a variety of thin film inorganic layer deposition, such as chemical vapor deposition (CVD), plasma enhanced chemical vapor deposition (PECVD), or physical vapor deposition, such as sputtering or evaporative deposition, evaporation of a polymer, or a combination thereof. In a further example, the barrier polymer layer can be coated by atomic layer deposition techniques. A fluoropolymer layer can be coated with an adhesive or the adhesive can be coated on the inorganic layer of the barrier film and the fluoropolymer adhered to or laminated to the barrier film. An encapsulant can be coated on or laminated to an opposite side of the protective film from the fluoropolymer.

The protective film can be laminated to a photovoltaic structure to form the photovoltaic device. For example, a photovoltaic component can be dispensed and a protective film including a multilayer laminate applied over the photovoltaic component. Optionally, an encapsulant can be laminated to the photovoltaic component prior to application of the protective film and the protective film can be laminated to the encapsulant. Alternatively, a barrier film can be applied over the photovoltaic component separately from the adhesive and fluoropolymer layers.

### EXAMPLES

### Example 1

A polyurethane adhesive (Bostik 179/74) is blended with 2 wt % of a benzotriazole ultraviolet radiation absorber and 0.5 wt % of an oligomeric hindered amine light stabilizer (HALS). Transmission over wavelengths from 280 nm to 480 nm is compared with a polyurethane adhesive absent the ultraviolet radiation absorber or the HALS, both initially and after exposure to UVB radiation for 150 hours using a ULB 313EL bulb available from QLab Corporation of Cleveland, Ohio.

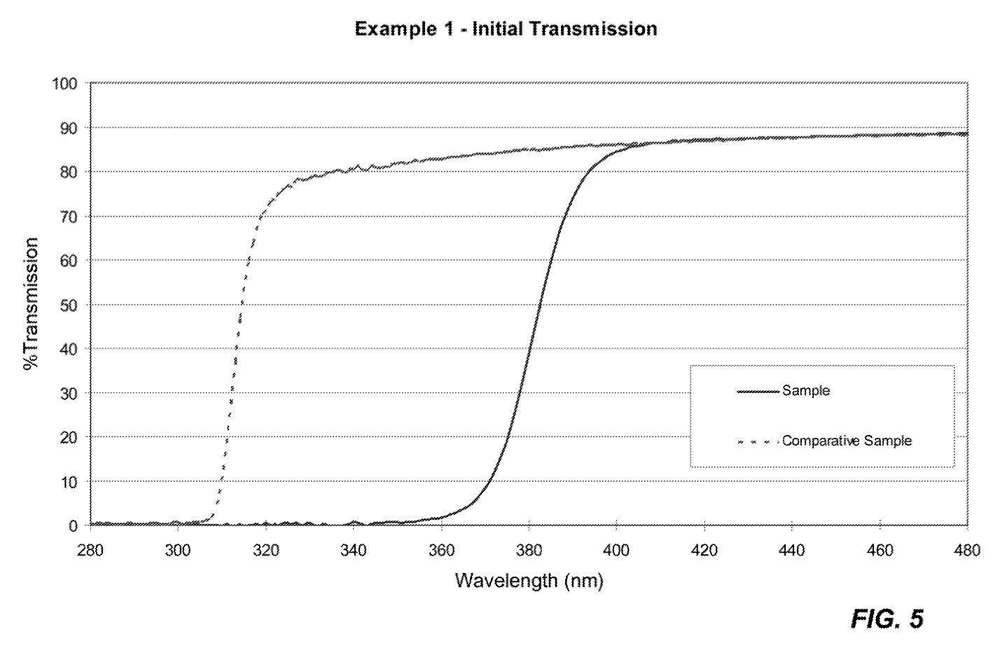

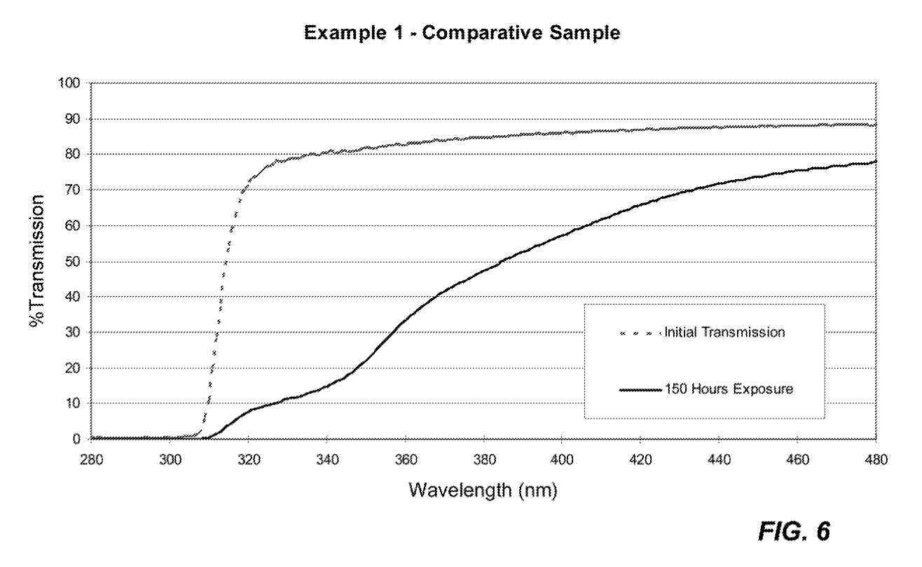

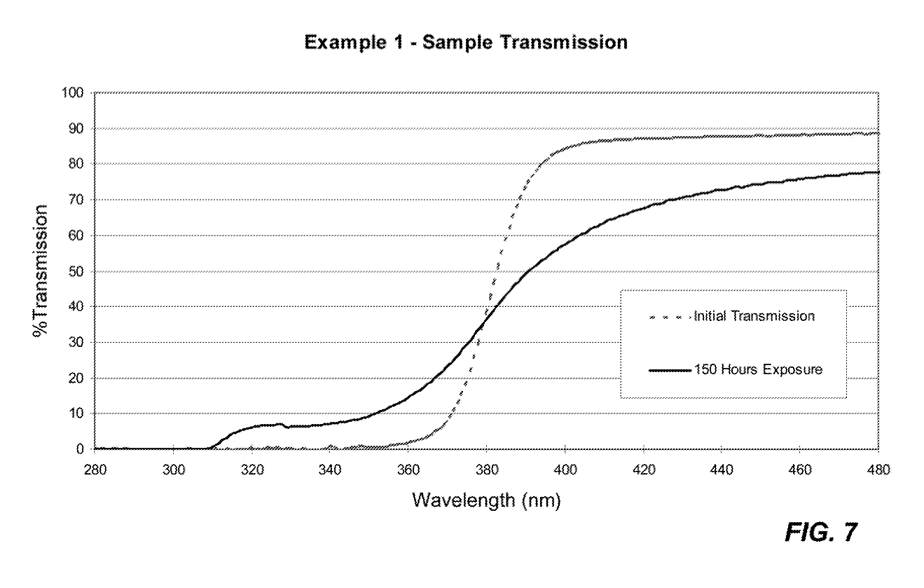

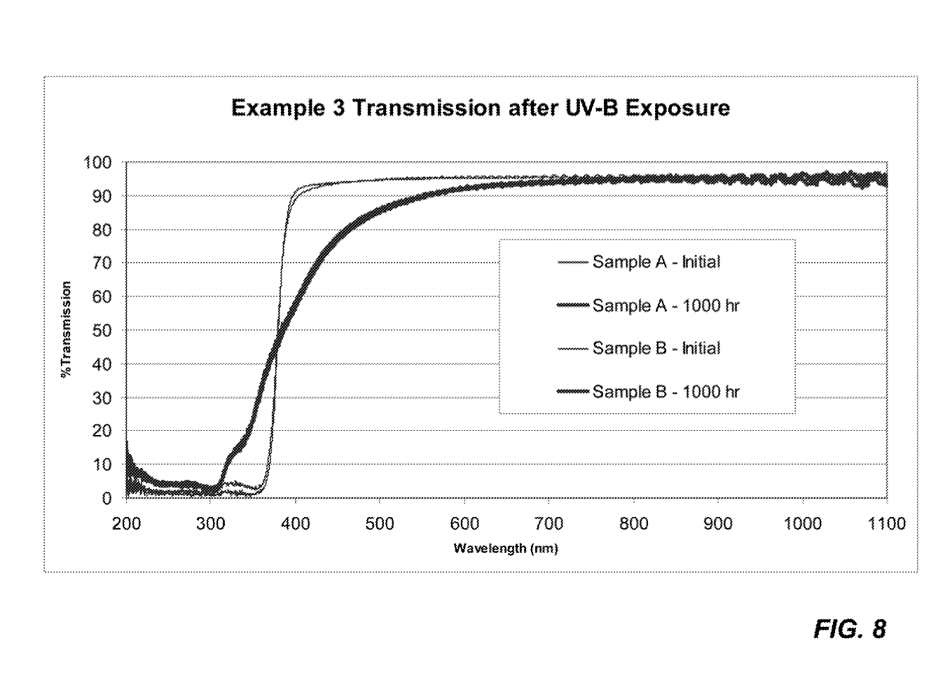

FIG. 5 illustrates the initial absorption of UV radiation by the samples. The comparative samples have high transmission at 320 nm whereas the samples including the ultraviolet radiation absorber exhibit substantial blocking at wavelengths as high as 350 nm and higher.

As illustrated in FIG. 6, the comparative example darkens with exposure to UVB over a period of 150 hours. While the resulting damage blocks some UV radiation, the damage also results in low transmission in the visible spectrum. In contrast, FIG. 7 illustrates that the polyurethane adhesive samples including ultraviolet radiation absorber block a greater portion of UV radiation. Although some yellowing is observed, after 150 hours, the adhesive has lower transmission in the UV spectrum and similar transmission in the visible spectrum. After 150 hours of exposure, samples with the 2 wt % of ultraviolet radiation absorber and 0.5 wt % HALS appear to lose effectiveness, yellowing and blocking less UV radiation.

### Example 2

Samples are prepared using a polyurethane adhesive blended with a benzotriazole ultraviolet radiation absorber or an oligomeric hindered amine light stabilizer (HALS). Samples of 0.3-mil or 1-mil thickness are blended with 0 wt % or 10 wt % of the ultraviolet radiation absorber and 0 wt % or 2.5 wt % of the HALS. The adhesive samples are applied between 50 micrometer thick ETFE films and tested for film damage, yellowing, and visible light transmission.

Yellowing is expressed using one or both of Delta-b Index or Yellowing Index. Delta-b Index after exposure for a specified period is determined by exposing the sample film to UVB for the specified period (using a ULB 313EL bulb available from QLab Corporation of Cleveland, Ohio) and testing the change in b* using the CIELAB (CIE 1976) testing method. Yellowing Index after exposure for a specified period is determined by exposing the sample film to UVB for the specified period (using a ULB 313EL bulb available from QLab Corporation of Cleveland, Ohio) and measuring the change in % transmission at 400 nm.

UV Blocking after exposure for a specified period can be determined by the change in % transmission at 330 nm following exposure to UVB using a ULB 313EL bulb available from QLab Corporation of Cleveland, Ohio for the specified period, defined as the Blocking Index.

TABLE 1
Adhesive Performance with Exposure to UVB

| | | | | Delta-b | Yellowing | Blocking |
|---|---|---|---|---|---|---|
| | Thickness | UVA | HALS | Index at | Index at | Index at |
| Sample | (mils) | (wt %) | (wt %) | 160 hr | 200 hr (%) | 374 hr (%) |
| 1 | 0.3 | 0 | 0 | 3.4 | 4.3 | 84.9 |
| 2 | 0.3 | 0 | 2.5 | 2.7 | 3.2 | 85.7 |
| 3 | 0.3 | 10 | 0 | 3.4 | 13.2 | 7.5 |
| 4 | 0.3 | 10 | 2.5 | 2.9 | 9.4 | 3.4 |
| 5 | 1.0 | 0 | 0 | 10.5 | 25.5 | 24.0 |
| 6 | 1.0 | 0 | 2.5 | 8.2 | 20.2 | 27.5 |
| 7 | 1.0 | 10 | 0 | 3.3 | 11.2 | 0.5 |
| 8 | 1.0 | 10 | 2.5 | 3.0 | 8.6 | 0.0 |

TABLE 2
Adhesive Performance with Exposure to UVB after 800 hours

| | Thickness | UVA | HALS | Delta-b Index |
|---|---|---|---|---|
| Sample | (mils) | (wt %) | (wt %) | at 800 hr |
| 1 | 0.3 | 0 | 0 | 0.1 |
| 2 | 0.3 | 0 | 2.5 | 0.0 |
| 3 | 0.3 | 10 | 0 | 1.5 |
| 4 | 0.3 | 10 | 2.5 | 2.0 |
| 5 | 1.0 | 0 | 0 | 19.8 |
| 6 | 1.0 | 0 | 2.5 | 12.5 |
| 7 | 1.0 | 10 | 0 | 5.8 |
| 8 | 1.0 | 10 | 2.5 | 5.8 |

Table 1 illustrates that reduced Yellowing Index is observed for samples including more of the HALS and a reduced Delta-b Index is observed for samples including more HALS and more ultraviolet radiation absorber.

### Example 3

Samples are prepared from an acrylic optically clear adhesive (OCA) disposed between 50 micrometer ETFE films. The acrylic is blended with 10 wt % of a benzotriazole ultraviolet radiation absorber. The samples are tested for transmission over a 1000 hour period. As illustrated in FIG. 8, the transmission in the visible spectrum decays slightly, but the transmission in the UV spectrum remains low over the 1000 hour exposure.

### Example 4

A sample tie layer adhesive is prepared from EVA, 0.01 wt % to 5 wt % of a hindered amine light stabilizer, 0.05 wt % to 5 wt % of a phosphite antioxidant, and 0.05 wt % to 10 wt % of a benzophenone light absorber.

### Example 5

Samples are prepared from an acrylic optically clear adhesive (OCA) disposed between 50 micrometer ETFE films to determine relative degradation resistance of UV blocking adhesive formulations. The acrylic is blended with different relative amounts of two different UV radiation absorbers, a triazine and a benzotriazole obtained from BASF (Table 1). The thickness of the adhesive is kept at 1 mil throughout. The samples are tested for transmission over a 1991 hour period of UV-A radiation (using a UVA-340 bulb available from QLab Corporation of Cleveland, Ohio). As illustrated in table 3, the Delta-b index is lowest at 10 wt % total additive concentration. Delta-b Index after exposure to UVA for a specified period is determined by exposing the sample film to UVA for the specified period (1991 hours) and testing the change in b* using the CIELAB (CIE 1976) color system.

In addition, none of the samples show evidence of precipitation or segregation of the additive, even though levels higher than in typical commercial preparations are prepared. Typical commercial preparations generally do not contain ultraviolet additive at greater than 2 wt % due to the segregation of the additive at levels higher than 2 wt %.

TABLE 3
Adhesive Performance with Exposure to UVA

| | UV Additive #1 | UV Additive #2 | Delta-b Index at |
|---|---|---|---|
| Sample | (wt %) Triazine | (wt %) Benzotriazole | 1991 hours |
| 1 | 5.0 | 0.0 | 10.0 |
| 2 | 0.0 | 5.0 | 10.4 |
| 3 | 5.0 | 5.0 | 9.1 |
| 4 | 0.0 | 0.0 | 16.7 |
| 5 | 0.0 | 10.0 | 8.7 |
| 6 | 10.0 | 0.0 | 5.5 |
| 7 | 3.33 | 3.33 | 9.5 |

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

After reading the specification, skilled artisans will appreciate that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

1. A multilayer film comprising:
a functional portion including one or more layers;
an adhesive layer overlying a major surface of the functional portion, the adhesive layer comprising an adhesive and an ultraviolet radiation absorber; and
a fluoropolymer layer overlying a major surface of the adhesive layer opposite the functional portion, the fluoropolymer layer comprising a fluoropolymer.

2. The multilayer film of claim 1, wherein the adhesive layer comprises at least 5.5 wt % of the ultraviolet radiation absorber.

3-4. (canceled)

5. The multilayer film of claim 1, wherein the ultraviolet radiation absorber is selected from the group consisting of a benzotriazole class absorber, a triazine class absorber, a benzophenone class absorber, a cyanoacrylate class absorber, a benzoxazinone class absorber, an oxanilide class absorber, and combinations thereof.

6-11. (canceled)

12. The multilayer film of claim 1, wherein the adhesive comprises acrylic adhesive.

13. The multilayer film of claim 1, wherein the adhesive is an optically clear adhesive.

14. The multilayer film of claim 1, wherein the fluoropolymer is selected from the group consisting of polyvinylidene fluoride (PVDF), polyvinyl fluoride (PVF), polytetrafluoroethylene (PTFE), a copolymer of tetrafluoroethylene and perfluoro methylvinylether (PFA), ethylene tetrafluoroethylene copolymer (ETFE), polychlorotrifluoroethylene (PCTFE), ethylene chlorotrifluoroethylene copolymer (ECTFE), fluorinated ethylene propylene copolymer (FEP), a copolymer of ethylene and fluorinated ethylene propylene (EFEP), a terpolymer of tetrafluoroethylene, hexafluoropropylene, and vinylidene fluoride (THV), a terpolymer of tetrafluoroethylene, hexafluoropropylene, and ethylene (HTE), and any combination thereof.

15-16. (canceled)

17. The multilayer film of claim 1, wherein the functional portion comprises a barrier polymer layer.

18. (canceled)

19. The multilayer film of claim 17, wherein the barrier polymer layer comprises polyester.

20-22. (canceled)

23. The multilayer film of claim 17, wherein the functional portion further includes an inorganic barrier material disposed on the barrier polymer layer.

24. (canceled)

25. The multilayer film of claim 1, wherein the functional portion has a water vapor transmission rate of not greater than 0.4 g/m² day.

26-28. (canceled)

29. The multilayer film of claim 1, further comprising an encapsulant layer disposed on the functional portion on a major surface opposite the adhesive layer.

30. The multilayer film of claim 1, wherein the adhesive layer has a thickness in a range of 0.1 mils to 4 mils.

31-38. (canceled)

39. The multilayer film of claim 1, wherein the multilayer film has a visible light transmission of at least 85%.

40-41. (canceled)

42. The multilayer film of claim 1, wherein the multilayer film exhibits a Delta-b Index of not greater than 5.0 after 160 hours when exposed to UVB.

43. The multilayer film of claim 1, wherein the multilayer film exhibits a Delta-b Index of less than 10.0 after 1991 hours when exposed to UVA.

44. A photovoltaic device comprising:
a photovoltaic component;
a first polymer layer overlying a major surface of the photovoltaic component;
a second polymer layer overlying a major surface of the first polymer layer opposite the photovoltaic component, the second polymer layer comprising an adhesive and an ultraviolet radiation absorber; and
a third polymer layer overlying a major surface of the second polymer layer opposite the first polymer layer, the third polymer layer comprising a fluoropolymer.

45. The photovoltaic component of claim 44, wherein the second polymer layer comprises at least 5.5 wt % of the ultraviolet radiation absorber.

46. (canceled)

47. The photovoltaic component of claim 44, wherein the ultraviolet radiation absorber is selected from the group consisting of a benzotriazole class absorber, a triazine class absorber, a benzophenone class absorber, a cyanoacrylate class absorber, a benzoxazinone class absorber, an oxanilide class absorber, and combinations thereof.

48. The photovoltaic component of claim 44, wherein the adhesive is an acrylic adhesive.

49-51. (canceled)

52. The photovoltaic component of claim 44, wherein the first polymer layer comprises a barrier polymer.

53. The photovoltaic component of claim 52, wherein the barrier polymer forms a film coated with an inorganic barrier material.

54. (canceled)

55. The photovoltaic component of claim 44, further comprising a fourth polymer layer disposed between the photovoltaic component and the first polymer layer, the fourth polymer layer comprising an encapsulant.

56-61. (canceled)

62. A method of forming a multilayer film, the method comprising:
providing a fluoropolymer layer;
providing a functional layer;
disposing an adhesive layer between the fluoropolymer layer and the functional layer, the adhesive layer comprising an adhesive and an ultraviolet radiation absorber; and
laminating the fluoropolymer layer, the adhesive layer, and the functional layer.

63. The method of claim 62, wherein the functional layer comprises a barrier polymer layer coated with an inorganic material layer, the adhesive in contact with the inorganic material layer.

64. The method of claim 62, further comprising coating an encapsulant layer on the functional layer on a surface opposite the adhesive layer.
